(19) United States
(12) Patent Application Publication
(10) Pub. No.: US 2024/0395620 A1
(43) Pub. Date: Nov. 28, 2024

(54) WAFER PROCESSING METHOD

(71) Applicant: DISCO CORPORATION, Tokyo (JP)

(72) Inventor: Jonghyun RYU, Tokyo (JP)

(21) Appl. No.: 18/664,720

(22) Filed: May 15, 2024

(30) Foreign Application Priority Data
May 24, 2023 (JP) 2023-085165

(51) Int. Cl. H01L 21/78; H01L 21/683

(52) U.S. Cl. CPC H01L 21/78; H01L 21/6836

(57) ABSTRACT

A wafer processing method for processing a wafer includes a reverse side which has an annular protruding portion on an outer circumferential portion thereof and a circular recessed portion in a region surrounded by the annular protruding portion on the reverse side, in which a sheet including no glue layer is fixed to a face side of the wafer and an annular frame is fixed to an outer circumferential portion of the sheet to form a wafer unit, the wafer is held on a holding table via the sheet, a dividing groove is formed in the circular recessed portion of the wafer, the annular protruding portion is separated from the wafer, and the annular protruding portion is removed from the sheet.

### BACKGROUND OF THE INVENTION

### Field of the Invention

The present invention relates to a wafer processing method for a wafer that has a reverse side in which an annular protruding portion is provided on an outer circumferential portion thereof and a circular recessed portion is formed in a region surrounded by the annual protruding portion.

### Description of the Related Art

Electronic equipment as exemplified by mobile phones and personal computers has device chips mounted thereon. Device chips are typically manufactured by a wafer having a plurality of devices such as integrated circuits (ICs) formed on a face side thereof being ground and thinned on a reverse side thereof and then divided by each device. The ground and thinned wafer has low rigidity and is thus liable to crack. Hence, a region which is part of the reverse side of the wafer and which corresponds to a device formed region in which the plurality of devices are formed is ground to form a circular recessed portion, and a portion around this circular recessed portion is left as an annular protruding portion. This annular protruding portion exhibits a function of reinforcing the thinned circular recessed portion when the wafer is being delivered, for example (see, for example, Japanese Patent Laid-open No. 2007-173487).

However, the annular protruding portion hinders division of the wafer into individual chips, and thus needs to be removed from the wafer in advance. When the annular protruding portion is to be removed, an adhesive tape is affixed to an entire region of the reverse side of the wafer including the circular recessed portion and the annular protruding portion, and the wafer is held on a holding table through the adhesive tape. The holding table has a protruding shape corresponding to the circular recessed portion of the wafer, and the circular recessed portion is fitted to this protruding shape. Further, an annular dividing groove is formed in the wafer held on the holding table, and the annular protruding portion is removed (see, for example, Japanese Patent Laid-open No. 2011-61137). Alternatively, as another method for removing the annular protruding portion from the wafer, there is known a method in which an adhesive tape is affixed to a face side of the wafer, the wafer is held under suction on a flat holding table via the adhesive tape, and a dividing groove for cutting off the annular protruding portion is formed in the wafer (see, for example, Japanese Patent Laid-open No. 2012-54275).

### SUMMARY OF THE INVENTION

In the case of removing the annular protruding portion by any of the methods described above, an annular frame is affixed to an outer circumferential portion of the adhesive tape which is to be affixed to the wafer. In this instance, the wafer is housed in an opening formed in the annular frame. When the processing of forming a dividing groove is performed on the wafer, processing swarf is generated from the wafer and the like and scatters around. Some scattered processing swarf sticks to the adhesive tape exposed in the opening of the annular frame. Further, in the process of delivery, processing, and the like of the wafer, some processing swarf scatters again and sticks to the wafer, causing a problem. Moreover, after a dividing groove is formed in the wafer and the annular protruding portion is cut off from the wafer, the cut-off annular protruding portion is peeled off from the adhesive tape. However, since the annular protruding portion is affixed by a great force to the adhesive tape including a glue layer before being separated from the wafer, a large force is needed to peel off the annular protruding portion from the adhesive tape. Moreover, the large force applied to the annular protruding portion causes cracking of the annular protruding portion, causing fragments to scatter toward the wafer.

In light of such circumstances, one possible solution is to affix, to the wafer and the annular frame, an adhesive tape including a glue layer that declines in adhesion by ultraviolet (UV) ray application. In this case, when the annular protruding portion which has been cut off from the wafer is to be peeled off from the adhesive tape, UV ray is applied to the adhesive tape at a region overlapping with the annular protruding portion, and the adhesion of the glue layer is reduced. At this time, a shielding member is used to avoid UV ray application to the region overlapping with the circular recessed portion. However, in order to apply UV rays at sufficient intensity to the region overlapping with the annular protruding portion, the size of the region which can be shielded by the shielding member is limited. Hence, UV rays are also applied to the adhesive tape at the region overlapping with the outer circumferential portion of the wafer, and the adhesion of the adhesive tape is lowered in this region. When the processing of dicing the wafer is performed at a portion of the adhesive tape where the adhesion has lowered, the wafer is not sufficiently supported at the portion, resulting in low quality processing. This requires the region to be used in forming devices on the face side of the wafer to be narrowed, leading to reduced productivity.

It is accordingly an object of the present invention to provide a wafer processing method that processes a wafer having an annular protruding portion, with high quality and high productivity.

In accordance with an aspect of the present invention, there is provided a wafer processing method for processing a wafer including a reverse side which has an annular protruding portion on an outer circumferential portion thereof and a circular recessed portion in a region surrounded by the annular protruding portion, the wafer processing method including a wafer unit forming step of forming a wafer unit by fixing a sheet including no glue layer to a face side of the wafer and fixing an annular frame to an outer circumferential portion of the sheet, a holding step of holding the wafer on a holding table via the sheet, after the wafer unit forming step, a dividing step of forming a dividing groove in the circular recessed portion of the wafer and separating the annular protruding portion from the wafer, after the holding step, and a removing step of removing the annular protruding portion from the sheet, after the dividing step.

Preferably, in the wafer unit forming step, the sheet is fixed to the wafer by being heated, pressed against, and thermocompression-bonded to the wafer.

In the wafer processing method according to an aspect of the present invention, the wafer unit is formed by a sheet including no glue layer being fixed to the wafer and the annular frame. Since the sheet includes no glue layer, even when processing swarf that is generated when a dividing groove is formed in the wafer comes into contact with the sheet, the processing swarf does not stick to the sheet. Further, even when the annular protruding portion breaks and fragments are generated when the annular protruding portion is removed from the sheet, the fragments do not stick to the sheet. Moreover, the processing swarf and the fragments that have come into contact with the sheet are easily removed from the sheet by cleaning.

Further, unlike the case in which the wafer is strongly stuck to an adhesive tape by a glue layer, in the case in which the wafer is fixed to the sheet including no glue layer, the annular protruding portion can be removed from the sheet relatively easily. Thus, no large force acts on the annular protruding portion to be removed, making it less likely for breakage to occur or fragments to be generated. Hence, processing swarf or fragments that have come into contact with the sheet are unlikely to move to the wafer (device chips) and deteriorate the quality of the device chips. Furthermore, UV rays need not be applied to the sheet for removing the annular protruding portion from the sheet, so that the region in the face side of the wafer that is to be used for device formation does not need to be narrowed down on the assumption that UV rays are to be applied thereto. This also increases the productivity of device chips.

Therefore, one aspect of the present invention provides a wafer processing method that processes a wafer having an annular protruding portion, with high quality and high productivity.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically illustrating a reverse side of a wafer;

FIG. 1B is a perspective view schematically illustrating a face side of the wafer;

FIG. 2A is a cross sectional view schematically illustrating a thermocompression bonding apparatus;

FIG. 2B is a cross sectional view schematically illustrating the thermocompression bonding apparatus in a first stage of a wafer unit forming step;

FIG. 3A is a cross sectional view schematically illustrating the thermocompression bonding apparatus in a second stage of the wafer unit forming step;

FIG. 3B is a cross sectional view schematically illustrating the thermocompression apparatus in a third stage of the wafer unit forming step;

FIG. 4 is a cross sectional view schematically illustrating the thermocompression bonding apparatus in a fourth stage of the wafer unit forming step;

FIG. 5 is a perspective view schematically illustrating a wafer unit;

FIG. 6A is a perspective view schematically illustrating the wafer unit in a holding step;

FIG. 6B is a cross sectional view schematically illustrating the wafer unit in the holding step;

FIG. 7A is a perspective view schematically illustrating the wafer unit in a dividing step;

FIG. 7B is a cross sectional view schematically illustrating the wafer unit in the dividing step;

FIG. 8A is a perspective view schematically illustrating the wafer unit in a removing step;

FIG. 8B is a cross sectional view schematically illustrating the wafer unit in the removing step; and

FIG. 9 is a flowchart illustrating a flow of steps of a wafer processing method according to an embodiment of the present invention.

### DETAILED DESCRIPTION OF THE PREFERRED EMBODIMENT

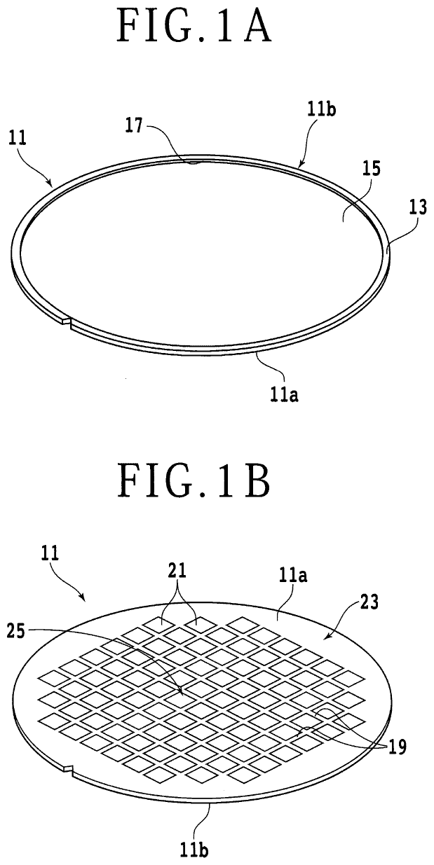

An embodiment according to one aspect of the present invention will be described with reference to the attached drawings. FIG. 1A is a perspective view schematically illustrating a reverse side 11b of a wafer 11, while FIG. 1B is a perspective view schematically illustrating a face side 11a of the wafer 11. First, the wafer 11 to be processed by a wafer processing method according to the present embodiment will be described.

The wafer 11 is a circular plate-shaped single crystal substrate formed of a semiconductor material such as silicon (Si) or silicon carbide (SiC), for example. Note, however, that there are no limitations on the shape, structure, size, and the like of the wafer 11. As illustrated in FIG. 1B, on the face side 11a of the wafer 11, a plurality of projected dicing lines 19 are set in a grid pattern. In regions partitioned by the plurality of projected dicing lines 19, devices 21 as exemplified by ICs and large-scale integration (LSI) circuits are formed. A region that is part of the face side 11a of the wafer 11 and that is on an outer circumferential portion surrounding a region in which the plurality of devices 21 are formed is called an outer circumferential surplus region 23. Further, a region that is part of the face side 11a of the wafer 11, that is surrounded by the outer circumferential surplus region 23, and in which the plurality of devices 21 are formed is called a device formed region 25.

When the wafer 11 in which the plurality of devices 21 are formed is ground and thinned from the reverse side 11b and is diced along the projected dicing lines 19, a plurality of thin device chips each including the device 21 can be obtained. Dicing the wafer 11 is, for example, performed by a cutting apparatus including an annular cutting blade. However, a ground and thinned wafer 11 has low rigidity and is liable to cracking, thus being difficult to handle upon delivery, for example. As such, as illustrated in FIG. 1A, a region that is part of the reverse side 11b of the wafer 11 and that corresponds to the device formed region 25 in which the plurality of devices 21 are formed is ground to form a circular recessed portion 15, and a portion around the circular recessed portion 15 is left as an annular protruding portion 13. This annular protruding portion 13 exhibits a function of reinforcing the thinned circular recessed portion 15, when the wafer 11 is being delivered, for example. This preserves the rigidity of the wafer 11, making it less likely for warp and cracking to occur and easier to handle the wafer 11.

However, when the wafer 11 having the annular protruding portion 13 on the reverse side 11b is to be directly diced along the projected dicing lines 19 by the cutting apparatus, a dicing groove formed in the wafer 11 to dice the thin circular recessed portion 15 is insufficient for cutting off the thick annular protruding portion 13. In other words, the annular protruding portion 13 hinders the dicing of the wafer 11 into individual chips. Hence, the annular protruding portion 13 needs to be removed from the wafer 11 before the wafer 11 is diced. In the wafer processing method according to the present embodiment, a sheet including no glue layer is fixed to the entire region of the face side 11a of the wafer 11, by thermocompression bonding, for example. The wafer 11 is held on a holding table of a dicing apparatus via the sheet.

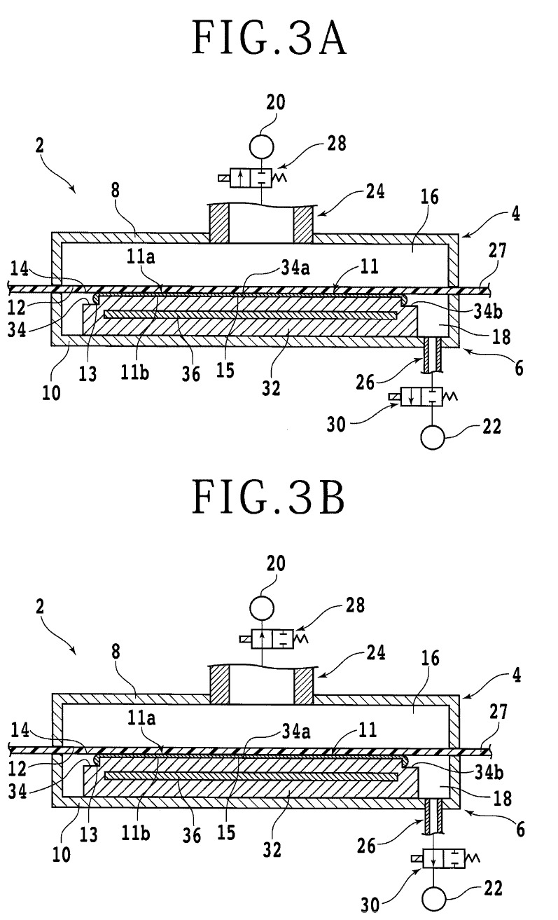

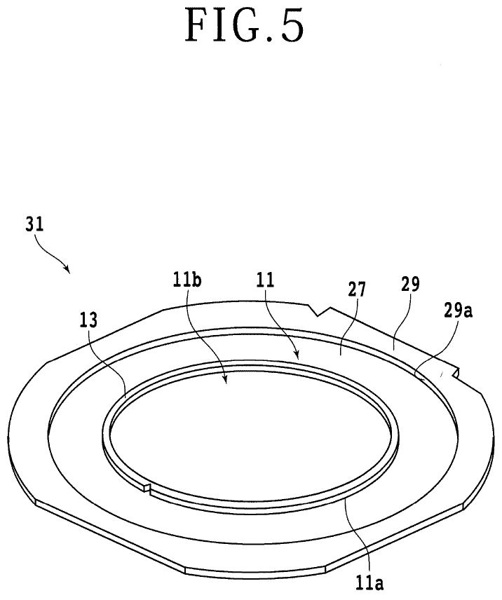

The sheet to be fixed to the wafer 11 will next be described. FIG. 3A and other relevant drawings include a cross sectional view schematically illustrating the sheet denoted by 27. FIG. 5 and other relevant drawings each include a perspective view schematically illustrating the sheet 27. The sheet 27 has a diameter larger than an outer diameter of the wafer 11 but includes no glue layer. Further, the sheet 27 is a sheet having thermoplasticity. An outer circumferential portion of the sheet 27 is disposed on an annular frame 29 made of metal (see FIG. 5 and other relevant drawings). The sheet 27 is, for example, a resin sheet having flexibility as exemplified by a polyolefin sheet and a polyester sheet, but the material of the sheet 27 is not limited to any of the above.

Here, a polyolefin sheet is a sheet of a polymer obtained by synthesizing alkenes as the monomer. The polyolefin sheet to be used for the sheet 27 is, for example, a sheet that is transparent or translucent with respect to visible light, such as a polyethylene sheet, a polypropylene sheet, or a polystyrene sheet. Moreover, a polyester sheet is a sheet of a polymer obtained by synthesizing a dicarboxylic acid (a compound containing two carboxyl groups) and a diol (a compound containing two hydroxyl groups) as the monomers. The polyester sheet to be used for the sheet 27 is, for example, a sheet that is transparent or translucent with respect to visible light, such as a polyethylene terephthalate sheet or a polyethylene naphthalate sheet.

Described from another perspective, the sheet 27 that is fixed to the wafer 11 by thermocompression bonding and that includes no glue layer is thermoplastic resin that has a storage elastic modulus of 1×10⁶ to 1×10⁹ Pa at room temperature and a storage elastic modulus of 1×10⁶ to 1×10⁷ Pa at the time of heating. Here, the time of heating refers to the time when the temperature at which the sheet 27 is thermocompression-bonded to the wafer 11 is reached. For example, in a case where the sheet 27 is a polyolefin sheet, the temperature is 80° C. to 100° C.

Note that the storage elastic modulus of the thermoplastic resin to be used as the constituent material of the sheet 27 can be evaluated by a viscoelasticity measurement instrument “DMA 7100” produced by Hitachi Hi-Tech Corporation. This viscoelasticity measurement instrument can calculate the temperature dependence and frequency dependence such as the storage elastic modulus, the loss elastic modulus, and loss tangent (tan δ), as the viscoelastic property of the sample, by causing periodic deformation to the sample and measuring the stress or distortion generated by such deformation. The measurement of the storage elastic modulus of the thermoplastic resin by the viscoelasticity measurement instrument can be performed, for example, under the condition of a rate of temperature increase of 2° C./min, a measurement temperature range of room temperature to 200° C., and a deformation frequency of 1 Hz. Note, however, that the measurement condition of the storage elastic modulus is not limited to those mentioned above. Further, the storage elastic modulus may be measured with use of another measurement apparatus.

Since the sheet 27 includes no glue layer (adhesive layer) and thus has insufficient adhesion, the sheet 27 cannot be affixed to the wafer 11 and the annular frame 29 in its original state. Yet, as the sheet 27 has thermoplasticity, when the sheet 27 is heated to a temperature close to the melting temperature in a state in which a predetermined pressure is applied and the sheet 27 is joined to the wafer 11, the sheet 27 partially melts down and can be fixed to the wafer 11. In other words, the sheet 27 can be thermocompression-bonded to the wafer 11.

Further, as illustrated in FIGS. 5, the outer circumferential portion of the sheet 27 is fixed to the annular frame 29 made of metal. The annular frame 29 includes an opening portion (through hole) 29a having a larger diameter than the wafer 11. For example, the sheet 27 is fixed to the annular frame 29 before being fixed to the wafer 11. The sheet 27 is, for example, fixed to the annular frame 29 by thermocompression-bonding. For example, the sheet 27 is thermocompression-bonded to the annular frame 29 together with the wafer 11. Alternatively, the sheet 27 is affixed and fixed to the annular frame 29 in advance by an adhesive, for example.

When the wafer 11, the sheet 27, and the annular frame 29 are finally integrated, a wafer unit 31 (see FIG. 5 and other relevant drawings) is formed. When the wafer unit 31 is formed, the wafer 11 can be handled via the sheet 27, making it easier to handle the wafer 11. Moreover, when the wafer 11 constituting part of the wafer unit 31 is diced, individual device chips formed from the wafer 11 are continuously supported by the sheet 27, also making it easier to handle the device chips.

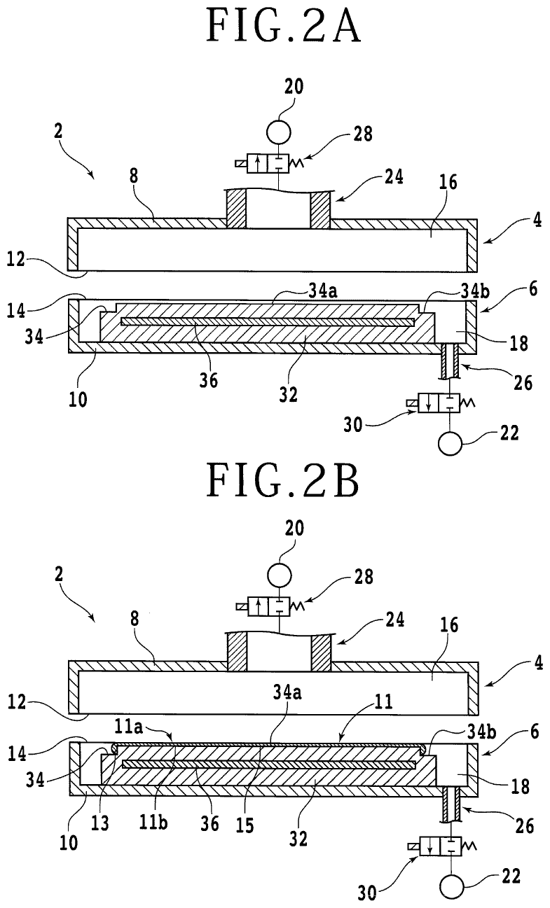

A description will next be given of a thermocompression bonding apparatus 2 that is used at the time of fixing the sheet 27 to the wafer 11 in the wafer processing method according to the present embodiment. Note, however, that the thermocompression bonding apparatus 2 need not be used at the time of fixing the sheet 27 to the wafer 11 in the wafer processing method according to the present embodiment. FIGS. 2A to 4 each include a cross sectional view schematically illustrating the thermocompression bonding apparatus 2.

FIG. 2A is a cross sectional view schematically illustrating an example of the thermocompression bonding apparatus 2. The thermocompression bonding apparatus 2 is, for example, a chamber-like unit having in its inside a space in which the wafer 11 can be housed, and has the function of thermocompression-bonding the sheet 27 to the face side 11a of the wafer 11. The thermocompression bonding apparatus 2 includes a recessed lower chamber 6 that is open upward and a recessed upper chamber 4 that is disposed above the lower chamber 6 and that is open downward. The upper chamber 4 of the thermocompression bonding apparatus 2 includes a first recessed portion 8 that is coupled to a first depressurizing unit 20 and that has a first opening 12. The lower chamber 6 includes a second recessed portion 10 that is coupled to a second depressurizing unit 22 and that has a second opening 14. The first depressurizing unit 20 and the second depressurizing unit 22 are, for example, vacuum pumps such as rotary pumps. Note, however, that the first depressurizing unit 20 and the second depressurizing unit 22 are not limited to such pumps. The thermocompression bonding apparatus 2 further includes a holding table 32 that is disposed on the second recessed portion 10 and that holds the wafer 11. When the first opening 12 of the upper chamber 4 and the second opening 14 of the lower chamber 6 are fit together, the upper chamber 4 and the lower chamber 6 can be closed.

A more detailed description will be given of the thermocompression bonding apparatus 2. The first opening 12 of the upper chamber 4 and the second opening 14 of the lower chamber 6 each have an inner diameter larger than the diameter of the wafer 11. The first recessed portion 8 of the upper chamber 4 and the second recessed portion 10 of the lower chamber 6 each have an outer diameter smaller than an inner diameter of the annular frame 29 that is disposed on the outer circumferential portion of the sheet 27. For example, the upper chamber 4 can be lifted and lowered. The second opening 14 of the lower chamber 6 and the first opening 12 of the upper chamber 4 have the same shape, and when the upper chamber 4 is lowered toward the lower chamber 6 such that the first opening 12 overlaps with the second opening 14, a space isolated from the outside is formed inside the upper chamber 4 and the lower chamber 6.

The lower chamber 6 is provided with the table-shaped holding table 32 that supports the wafer 11. On the holding table 32, the wafer 11 is placed with the reverse side 11b in which the annular protruding portion 13 and the circular recessed portion 15 are formed facing downward. An upper surface of the holding table 32 constitutes a holding surface 34 that supports and holds the wafer 11 from the reverse side 11b. The holding table 32 may include a suction channel (not illustrated) that communicates with the holding surface 34 and a suction source (not illustrated) that is connected to the suction channel. In this case, when a suction force generated at the suction source is caused to act, through the suction channel, on the wafer 11 placed on the holding surface 34 of the holding table 32, the wafer 11 can be held under suction on the holding table 32.

The holding table 32 includes a circular protruding portion 34a that mainly supports the circular recessed portion 15 on the reverse side 11b of the wafer 11 and an annular support portion 34b that is disposed on the outer circumference of the circular protruding portion 34a and that mainly supports the annular protruding portion 13 of the wafer 11. The planar shape of the upper surface of the circular protruding portion 34a is a shape that can be fit into the circular recessed portion 15 of the wafer 11 and is thus slightly smaller than that of the circular recessed portion 15. The annular support portion 34b has a width (distance between the inner circumference and the outer circumference) greater than the width (distance between the inner circumference and the outer circumference) of the annular protruding portion 13 of the wafer 11. The difference in height between the upper surface of the annular support portion 34b and the upper surface of the circular protruding portion 34a is equivalent to the difference in height between the circular recessed portion 15 and the annular protruding portion 13 of the wafer 11. Specifically, this difference is appropriately decided depending on the height of the step portion 17 (see FIG. 1A) between the circular recessed portion 15 and the annular protruding portion 13 of the wafer 11.

On the upper surface of the annular support portion 34b, an unillustrated spacer is disposed. The spacer is formed of an elastic member such as a resin layer, and changes in thickness according to variation in height difference (height of the step portion 17) between the circular recessed portion 15 and the annular protruding portion 13 of the wafer 11. That is, the holding table 32 can appropriately hold the wafer 11 while coping with the variation in height difference between the circular recessed portion 15 and the annular protruding portion 13 of the wafer 11.

The height of the holding table 32 is adjusted in such a manner that, when the wafer 11 is placed on the holding surface 34, the height of the face side 11a of the wafer 11 and the height of the second opening 14 of the lower chamber 6 become substantially the same. Alternatively, the height of the holding table 32 is adjusted in such a manner that the height of the second opening 14 of the lower chamber 6 becomes greater than the height of the face side 11a of the wafer 11.

To a ceiling or a sidewall of the upper chamber 4, an exhaust section 24 is connected. The exhaust section 24 is an exhaust passage which has one end connected to the first recessed portion 8 of the upper chamber 4 and another end connected to the first depressurizing unit 20. The exhaust passage of the exhaust section 24 is provided with a first electromagnetic valve 28 (for example, a solenoid valve) that switches the state of connection between the upper chamber 4 and the first depressurizing unit 20. Specifically, when the first electromagnetic valve 28 is operated, the state of connection between the upper chamber 4 and the first depressurizing unit 20 is switched between the two states: the state in which the two members are connected to each other and the state in which the two members are disconnected from each other. To a bottom wall or a sidewall of the lower chamber 6, an exhaust section 26 is connected. The exhaust section 26 is an exhaust passage which has one end connected to the second recessed portion 10 of the lower chamber 6 and another end connected to the second depressurizing unit 22. The exhaust passage of the exhaust section 26 is provided with a second electromagnetic valve 30 (for example, a solenoid valve) that switches the state of connection between the lower chamber 6 and the second depressurizing unit 22. Specifically, when the second electromagnetic valve 30 is operated, the state of connection between the lower chamber 6 and the second depressurizing unit 22 is changed between the two states: the state in which the two members are connected to each other and the state in which the two members are disconnected from each other.

When the first electromagnetic valve 28 is operated and the first depressurizing unit 20 and the upper chamber 4 are connected, an internal space 16 of the upper chamber 4 can be depressurized. Similarly, when the second electromagnetic valve 30 is operated and the second depressurizing unit 22 and the lower chamber 6 are connected, an internal space 18 of the lower chamber 6 can be depressurized.

The thermocompression bonding apparatus 2 includes a heating unit that heats the wafer 11 placed on the holding table 32 and the sheet 27 placed on the wafer 11. For example, inside the holding table 32, a heater 36 that can function as the heating unit is disposed. The heater 36 is, for example, a heating wire. When the heater 36 is operated, the wafer 11 is heated, and also the sheet 27 is heated through the wafer 11. Note, however, that the heating unit included in the thermocompression bonding apparatus 2 is not limited to the heater described above. For example, the first recessed portion 8 of the upper chamber 4 may be provided with a heating unit (not illustrated) that supplies heated air to the internal space 16 of the upper chamber 4. The heating unit includes, for example, an air blower that generates a flow of air and a heater that can heat air. When the wafer 11 is placed on the holding table 32, the sheet 27 is disposed on the wafer 11, and heated air is supplied to the sheet 27 from the heating unit, the sheet 27 can be heated.

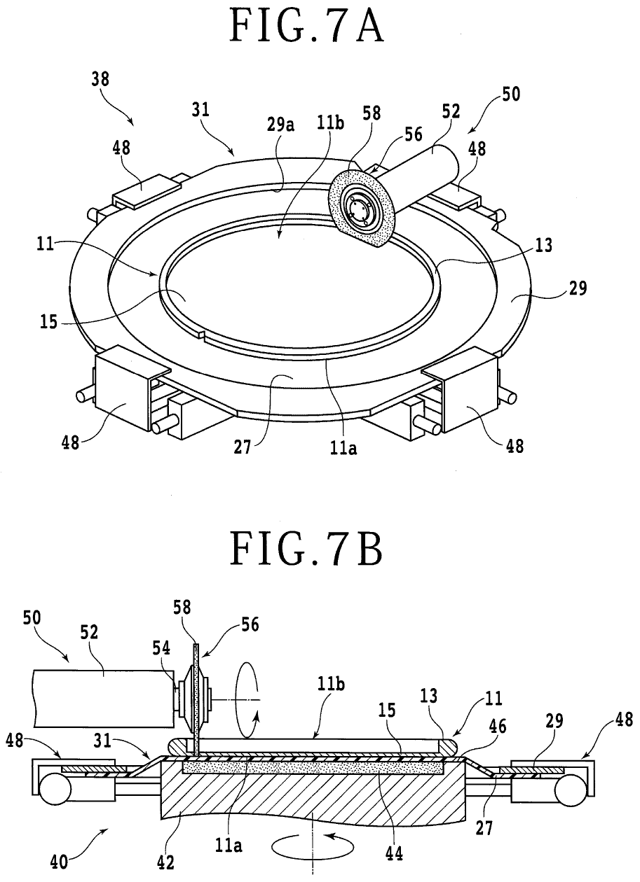

Next, a cutting apparatus to be used for removing the annular protruding portion 13 of the wafer 11 in the wafer processing method according to the present embodiment will be described. FIG. 7A includes a perspective view schematically illustrating the cutting apparatus, and FIG. 7B includes a cross sectional view schematically illustrating the cutting apparatus. The cutting apparatus denoted by 38 includes a holding table 40 that holds the wafer 11 (wafer unit 31) and a cutting unit 50 that cuts the wafer 11 held on the holding table 40.

The holding table 40 includes a porous member 44 that has a circular upper surface which is substantially the same size as the face side 11a of the wafer 11 and a frame body 42 that houses and exposes upward the porous member 44. The frame body 42 has on its upper surface a housing recessed portion for housing the porous member 44. Formed inside the frame body 42 is a suction channel (not illustrated) that has one end connected to the porous member 44 and another end connected to a suction source (not illustrated) such as an ejector. When the suction source is operated in a state in which the wafer 11 (wafer unit 31) is placed on the holding table 40, a negative pressure acts on the wafer 11 through the suction channel and the porous member 44. That is, the wafer 11 is held under suction on the holding table 40 via the sheet 27. Further, the upper surface of the holding table 40 becomes a holding surface 46. Further, a rotary drive source (not illustrated) such as a motor is coupled to the holding table 40 and rotates the holding table 40 about a rotational axis substantially parallel to the holding surface 46. Moreover, around the holding table 40, there may be provided a plurality of clamps 48 for gripping and fixing the annular frame 29 which supports the wafer 11 via the sheet 27.

On the upper side of the holding table 40, the cutting unit 50 that cuts the wafer 11 is disposed. The cutting unit 50 includes a cylindrical spindle 54 that is disposed along a direction substantially parallel to the holding surface 46 of the holding table 40. To a distal end portion (one end side) of the spindle 54, an annular cutting blade 56 that cuts the wafer 11 is mounted. Further, a proximal end portion (other end side) of the spindle 54 is rotatably housed in a spindle housing 52. A rotary drive source (not illustrated) such as a motor is housed in the spindle housing 52, and is coupled to the proximal end portion of the spindle 54. The cutting blade 56 rotates by power transmitted from the rotary drive source via the spindle 54.

As the cutting blade 56 mounted to the distal end portion of the spindle 54, for example, a cutting blade of a hub type (hub blade) is used. A hub blade is configured by integration of an annular base made of metal or the like and an annular cutting edge 58 formed along an outer circumferential edge of the base. The cutting edge 58 of the cutting blade of a hub type is configured by electroformed grindstones in which abrasive grains including diamond or the like are fixed by a binder such as a nickel plating layer. Yet, a cutting blade of a washer type (washer blade) can also be used as the cutting blade 56. The washer blade is configured by the annular cutting edge 58 in which abrasive grains are fixed by a binder including metal, ceramic, resin, or the like. In any case, the cutting blade 56 can cut the wafer 11 by the annular cutting edge 58.

The cutting unit 50 is connected to an unillustrated moving unit and can adjust the position where the cutting blade 56 cuts into the wafer 11. Further, the cutting unit 50 is connected to an unillustrated lifting/lowering unit and can change the height position of the lower end of the annular cutting edge 58.

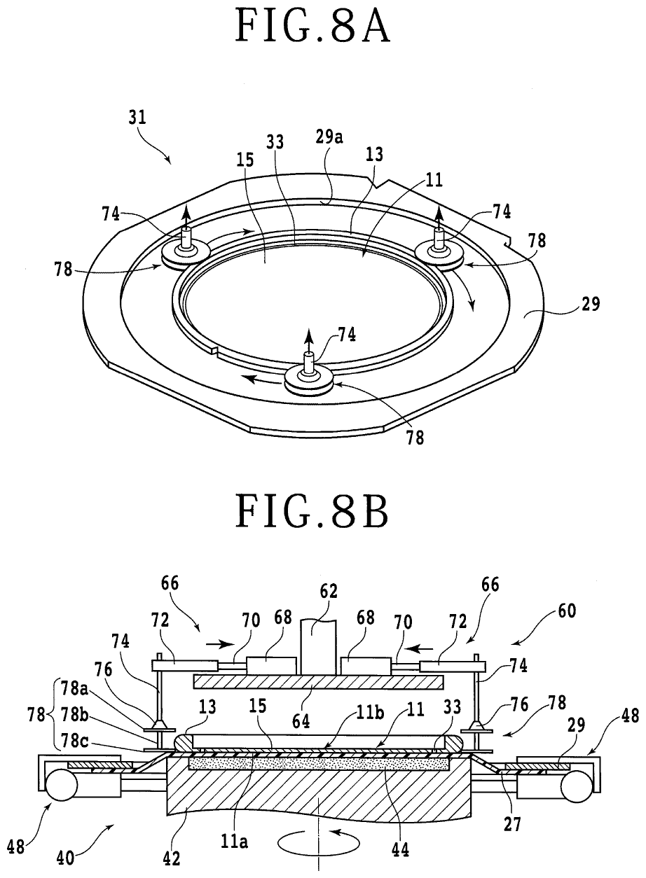

Next, a removing unit that removes, from the sheet 27, the annular protruding portion 13 that has been cut off from the wafer 11 in the wafer processing method according to the present embodiment will be described. FIG. 8B includes a cross sectional view schematically illustrating the removing unit denoted by 60. FIG. 8A includes a perspective view schematically illustrating a configuration of part of the removing unit 60.

The removing unit 60 includes a cylindrical arm portion 62 that is disposed substantially parallel to a height direction. The arm portion 62 is, for example, movable along the height direction and a horizontal direction by a height direction moving mechanism (not illustrated) and a horizontal direction moving mechanism (not illustrated) each being of a ball screw type. To a lower end portion of the arm portion 62, a central portion of a circular plate-shaped base plate 64 is coupled in a rotatable manner with respect to the arm portion 62. The arm portion 62 incorporates a rotary drive source (not illustrated) such as a motor. The rotary drive source rotates the base plate 64 in a predetermined direction.

Above the base plate 64, a plurality of removal claw units 66 are provided. Each removal claw unit 66 includes a linear-motion mechanism 68. The linear-motion mechanism 68 includes a ball screw mechanism (not illustrated) that advances and retracts an advancing/retracting rod 70. The advancing/retracting rod 70 includes a nut portion (not illustrated) that is slidably coupled to a guide portion of the linear-motion mechanism 68. The nut portion is rotatably coupled to a ball screw (not illustrated) of the linear-motion mechanism 68. When the nut portion is advanced or retracted by the linear-motion mechanism 68, the advancing/retracting rod 70 advances or retracts in the longitudinal direction. In the present embodiment, a plurality of advancing/retracting rods 70 are provided. The positions of the plurality of advancing/retracting rods 70 are point symmetric with respect to the arm portion 62 as the center.

To a distal end portion of each of the advancing/retracting rods 70, one end portion (proximal end portion) of a rectangular parallelepiped moving block 72 in the longitudinal direction is fixed. The advancing/retracting rod 70 is fixed to the moving block 72 in such a manner that the longitudinal direction of the advancing/retracting rod 70 and the longitudinal direction of the moving block 72 intersect within a horizontal plane. To the other end portion (distal end portion) of the moving block 72, a cylindrical rotational axis rod 74 is fixed in a manner extending vertically downward. To the lower end portion of the rotational axis rod 74, a removal claw 78 is coupled in a rotatable manner via a bearing 76.

The removal claw 78 includes an upper claw 78a and a lower claw 78b, each having a circular plate shape, and a cylindrical connection portion 78c that connects central portions of the upper claw 78a and the lower claw 78b. The upper claw 78a and the lower claw 78b are fixed to each other via the connection portion 78c. In the present embodiment, as illustrated in FIG. 8A, three removal claws 78 are disposed in a manner separated from one another at substantially equal intervals along the circumferential direction of the base plate 64, and are used to peel off the annular protruding portion 13 from the sheet 27 and support the peeled-off annular protruding portion 13 at three points. Note, however, that the number of removal claws 78 to be provided in the removing unit 60 is not limited to three, and four or more removal claws 78 may be provided in the removing unit 60.

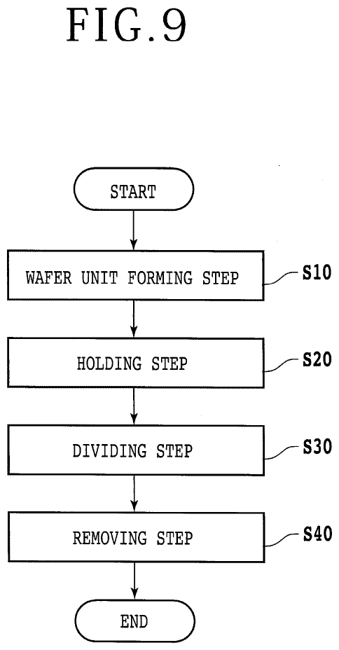

Next, steps of the wafer processing method according to the present embodiment will be described in detail. The wafer processing method according to the present embodiment is implemented as part of the device chip manufacturing method that dices the wafer 11 and forms device chips, for example. FIG. 9 is a flowchart illustrating a flow of the steps of the wafer processing method (device chip manufacturing method). In the following description, the wafer processing method according to the present embodiment will be described. Note, however, that the following description also applies to the steps of the device chip manufacturing method.

In the wafer processing method according to the present embodiment, first, a wafer unit forming step S10 is performed. In the wafer unit forming step S10, the sheet 27 including no glue layer is fixed to the face side 11a of the wafer 11, and the annular frame 29 is fixed to the outer circumferential portion of the sheet 27, to form the wafer unit 31. In the following description, the wafer unit forming step S10 will be described stage by stage.

FIG. 2B is a cross sectional view schematically illustrating the thermocompression bonding apparatus 2 and the wafer 11 at a first stage in the wafer unit forming step S10. At the first stage of the wafer unit forming step S10, the reverse side 11b of the wafer 11 is oriented downward, the wafer 11 is moved to a position above the holding table 32, and the reverse side 11b of the wafer 11 is caused to face the holding surface 34 of the holding table 32. Next, the wafer 11 is placed on the holding surface 34 of the holding table 32, the suction source of the holding table 32 is operated, and the wafer 11 is held under suction on the holding table 32. More specifically, the circular recessed portion 15 on the reverse side 11b of the wafer 11 is placed on the circular protruding portion 34a of the holding table 32, the annular protruding portion 13 on the reverse side 11b of the wafer 11 is placed on the annular support portion 34b of the holding table 32, and the wafer 11 is held under suction on the holding table 32. At this time, the face side 11a to which the sheet 27 is to be thermocompression-bonded is exposed upward.

Next, as a second stage of the wafer unit forming step S10, the sheet 27 is sandwiched by the upper chamber 4 and the lower chamber 6 of the thermocompression bonding apparatus 2, and the internal space 16 of the upper chamber 4 and the internal space 18 of the lower chamber 6 are hermetically closed. FIG. 3A is a cross sectional view schematically illustrating the thermocompression bonding apparatus 2 at the second stage of the wafer unit forming step S10. Note that the annular frame 29 (see FIG. 5 and other relevant drawings) may be fixed beforehand to the outer circumferential portion of the sheet 27. Fixing the sheet 27 to the annular frame 29 is performed by thermocompression-bonding of heating the sheet 27 and pressing the sheet 27 against the annular frame 29. Alternatively, thermocompression-bonding of the sheet 27 to the annular frame 29 may be performed simultaneously with the thermocompression-bonding of the wafer 11 to the sheet 27. As still another alternative, an adhesive may be sandwiched by the annular frame 29 and the sheet 27 to affix the annular frame 29 and the sheet 27 to each other, and thereby fix the sheet 27 to the annular frame 29. Alternatively, the sheet 27 may include a glue layer only at the outer circumferential portion and be affixed to the annular frame 29 by the glue layer.

At the second stage of the wafer unit forming step S10, a frame unit including the annular frame 29 having at its center the opening portion 29a capable of housing the wafer 11 and the sheet 27 the outer circumferential portion of which is fixed to the annular frame 29 is placed on the lower chamber 6. At this time, the second opening 14 of the lower chamber 6 is closed by the sheet 27. Note that, in this instance, the position of the annular frame 29 is adjusted such that the annular frame 29 does not overlap with the first opening 12 and the second opening 14. Subsequently, the upper chamber 4 is lowered, the sheet 27 of the frame unit is sandwiched by the first opening 12 of the first recessed portion 8 and the second opening 14 of the second recessed portion 10 at an inner side of the opening portion 29a of the annular frame 29, and the first recessed portion 8 and the second recessed portion 10 are closed. At this time, the internal space 16 of the upper chamber 4 is hermetically closed by the sheet 27 and the first recessed portion 8. Further, the internal space 18 of the lower chamber 6 is hermetically closed by the sheet 27 and the second recessed portion 10.

Next, as a third stage of the wafer unit forming step S10, the first recessed portion 8 is depressurized by the first depressurizing unit 20, and the second recessed portion 10 is depressurized by the second depressurizing unit 22. FIG. 3B is a cross sectional view schematically illustrating the thermocompression bonding apparatus 2 at the third stage of the wafer unit forming step S10. At the third stage of the wafer unit forming step S10, the first electromagnetic valve 28 is operated, and the first depressurizing unit 20 and the upper chamber 4 are connected to each other. As a result, air inside the internal space 16 of the first recessed portion 8 of the upper chamber 4 is exhausted by the first depressurizing unit 20 through the exhaust section 24, and the internal space 16 is depressurized. Then, the second electromagnetic valve 30 is operated, and the second depressurizing unit 22 and the lower chamber 6 are connected to each other. As a result, air inside the internal space 18 of the second recessed portion 10 of the lower chamber 6 is exhausted by the second depressurizing unit 22 through the exhaust section 26, and the internal space 18 is depressurized.

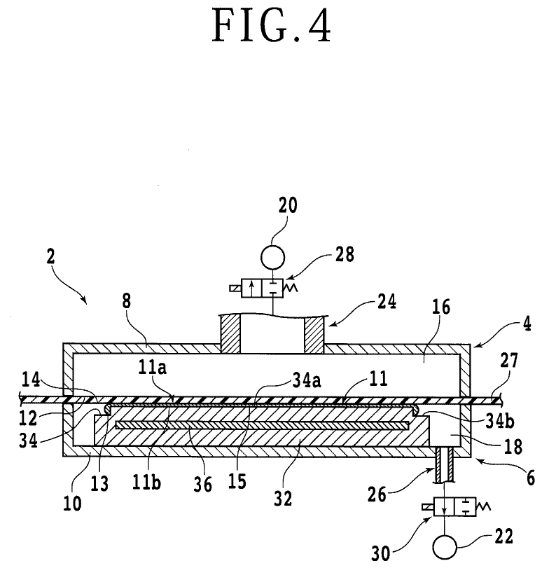

Subsequently, as a fourth stage of the wafer unit forming step S10, the pressure inside the first recessed portion 8 is increased, and the sheet 27 is caused to come into contact with the face side 11a of the wafer 11. For example, the sheet 27 is pressed against the wafer 11 and caused to come into contact with the wafer 11 with use of the difference in vertical pressure acting on the sheet 27. FIG. 4 is a cross sectional view schematically illustrating the thermocompression bonding apparatus 2 at the fourth stage of the wafer unit forming step S10. At the fourth stage of the wafer unit forming step S10, first, depressurizing the upper chamber 4 by the first depressurizing unit 20 is stopped. Specifically, the first electromagnetic valve 28 is operated to cancel the connection between the first depressurizing unit 20 and the upper chamber 4. At this time, the second electromagnetic valve 30 is not operated to maintain the connection between the second depressurizing unit 22 and the lower chamber 6. In this case, the pressure inside the internal space 16 of the upper chamber 4 gradually increases.

Alternatively, the thermocompression bonding apparatus 2 may have the upper chamber 4 connected to open air through the exhaust section 24 or other members. In this case, when the upper chamber 4 is connected to open air, air rapidly flows into the internal space 16, and the pressure inside the internal space 16 of the upper chamber 4 sharply increases. When the pressure inside the internal space 16 of the upper chamber 4 becomes higher than the pressure inside the internal space 18 of the lower chamber 6, a downward force acts on the sheet 27 that separates the internal space 16 and the internal space 18 from each other between the two internal spaces. As a result, the sheet 27 is pressed toward the face side 11a of the wafer 11.

At the fourth stage of the wafer unit forming step S10, the sheet 27 is pressed downward and comes into contact with the face side 11a of the wafer 11. Alternatively, the sheet 27 is already in contact with the face side 11a of the wafer 11 at the point in time when the fourth stage of the wafer unit forming step S10 is to be started, and the sheet 27 is pressed toward the wafer 11 at this fourth stage. When the fourth stage of the wafer unit forming step S10 is completed, such a force that is sufficient to fix the sheet 27 and the wafer 11 to each other is not acting between the two members. As such, in order to fix the sheet 27 to the wafer 11, the sheet 27 is heated, and thermocompression-bonded to the face side 11a of the wafer 11.

Next, as a fifth stage of the wafer unit forming step S10, the heating unit of the thermocompression bonding apparatus 2 is operated to heat the sheet 27. For example, when the thermocompression bonding apparatus 2 has the heater 36 as the heating unit, the heater 36 is operated to heat both the wafer 11 and the sheet 27. When the sheet 27 is heated to a temperature close to the melting temperature in a state of being pressed toward the wafer 11 due to a pressure difference between the internal space 16 of the first recessed portion 8 and the internal space 18 of the second recessed portion 10, the sheet 27 is thermocompression-bonded to the wafer 11. After the sheet 27 is thermocompression-bonded to the wafer 11, the heating unit (heater 36) is stopped, and the heating of the sheet 27 is stopped.

Note that, at the time of performing thermocompression bonding, the sheet 27 is preferably heated to a temperature that is equal to or lower than the melting temperature thereof. This is because, when the heating temperature exceeds the melting temperature, the sheet 27 may dissolve and be unable to maintain the sheet-shape. The sheet 27 is also preferably heated to a temperature that is equal to or higher than the softening temperature thereof. This is because thermocompression bonding would not be performed appropriately if the heating temperature has not reached the softening temperature. That is, the sheet 27 is preferably heated to a temperature that is equal to or higher than the softening temperature thereof but equal to or lower than the melting temperature thereof. Further, some sheets 27 may not have a specific softening temperature. Thus, at the time of performing thermocompression bonding, the sheet 27 is preferably heated to a temperature that is equal to higher than a temperature 20 degrees lower than the melting temperature thereof but equal to or lower than the melting temperature thereof.

For example, in a case where the polyolefin sheet to be used as the sheet 27 is a polyethylene sheet, the heating temperature is preferably 120° C. to 140° C. Alternatively, in a case when the polyolefin sheet is a polypropylene sheet, the heating temperature is preferably 160° C. to 180° C. In a case where the polyolefin sheet is a polystyrene sheet, the heating temperature is preferably 220° C. to 240° C. Further, in a case where the polyester sheet to be used as the sheet 27 is a polyethylene terephthalate sheet, the heating temperature is 250° C. to 270° C. Further, in a case where the polyester sheet is a polyethylene naphthalate sheet, the heating temperature is 160° C. to 180° C. Note, however, that the heating temperature of the sheet 27 is not limited to the abovementioned examples.

After the heating unit is stopped to stop heating the sheet 27, the second electromagnetic valve 30 is operated to cancel the connection between the second depressurizing unit 22 and the lower chamber 6, and the pressure inside the internal space 18 of the lower chamber 6 is restored back to atmospheric pressure, the upper chamber 4 is lifted. As a result, the wafer unit 31 in which the sheet 27, the wafer 11, and the annular frame 29 are integrated is obtained, as illustrated in FIG. 5. This completes the wafer unit forming step S10.

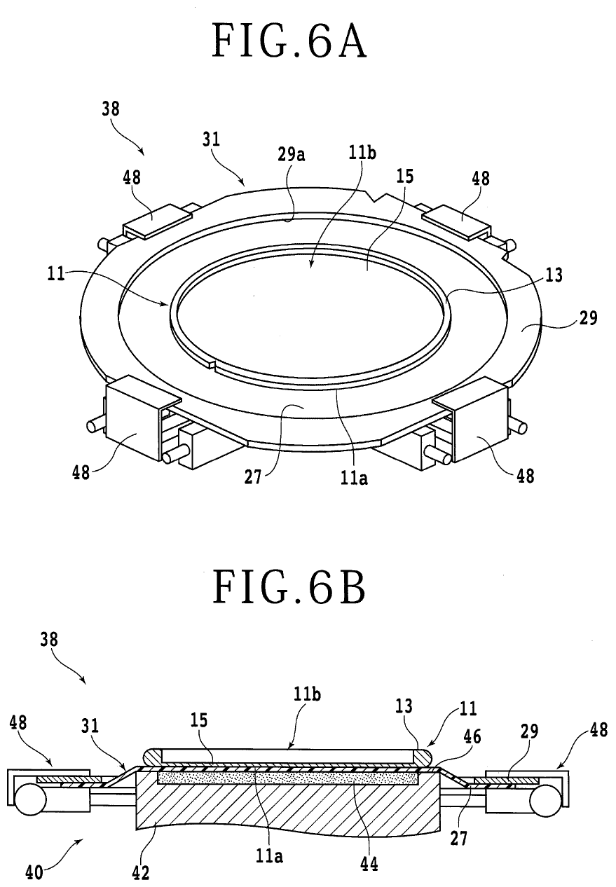

In the wafer processing method according to the present embodiment, after the wafer unit forming step S10, a holding step S20 of holding the wafer 11 by the holding table 40 of the cutting apparatus 38 via the sheet 27 is performed. FIG. 6A is a perspective view schematically illustrating the wafer unit 31 in the holding step S20, and FIG. 6B is a cross sectional view schematically illustrating the wafer unit 31 in the holding step S20. In the holding step S20, the wafer unit 31 is conveyed out from the thermocompression bonding apparatus 2, and is placed on the holding table 40 of the cutting apparatus 38. At this time, the face side 11a of the wafer 11 is caused to face the holding surface 46, and the position of the wafer 11 is adjusted such that the center of the holding surface 46 and the center of the face side 11a of the wafer 11 overlap with each other. Thereafter, a suction source (not illustrated) of the holding table 40 is operated, and the wafer 11 is held under suction on the holding table 40 via the sheet 27. Further, the annular frame 29 of the wafer unit 31 is gripped by the clamps 48 provided on the outer circumferential portion of the holding table 40. As a result, the reverse side 11b of the wafer 11 is exposed upward.

In the wafer processing method according to the present embodiment, after the holding step S20, a dividing step S30 of forming a dividing groove in the circular recessed portion 15 of the wafer 11 and separating the annular protruding portion 13 from the wafer 11 is performed. FIG. 7A is a perspective view schematically illustrating the cutting apparatus 38 in the dividing step S30, and FIG. 7B is a cross sectional view schematically illustrating the cutting apparatus 38 in the dividing step S30. FIGS. 8A and 8B each schematically illustrate a dividing groove 33 formed in the wafer 11.

The position in the wafer 11 where the dividing groove 33 is to be formed is set to a circular region having the center of the circular recessed portion 15 as the center. Especially, the position where the dividing groove 33 is to be formed is adjusted such that the cutting edge 58 does not cut into the step portion 17 between the annular protruding portion 13 and the circular recessed portion 15 illustrated in FIG. 1A. In the dividing step S30, first, the cutting unit 50 is moved, so that the cutting edge 58 of the cutting blade 56 is positioned above the region where the dividing groove 33 is to be formed. Next, the rotary drive source provided inside the spindle housing 52 is operated to start rotation of the cutting blade 56. The cutting unit 50 is then lowered, and the cutting edge 58 is caused to cut into the wafer 11. Subsequently, the cutting unit 50 is lowered to a height position where the lower end of the cutting edge 58 reaches the sheet 27, and the rotation of the holding table 40 is started. When the holding table 40 is rotated once or more, a circular dividing groove 33 is formed in the wafer 11, and the annular protruding portion 13 is cut off from the wafer 11. In other words, the annular protruding portion 13 and the circular recessed portion 15 are separated from each other.

Note that, when the cutting unit 50 cuts the wafer 11, cutting swarf and friction heat are produced from the wafer 11 and the cutting edge 58 of the cutting blade 56. Thus, when the cutting blade 56 cuts into the wafer 11, cutting water including pure water, for example, is supplied to the cutting blade 56 and the wafer 11. As a result, the cutting swarf and the friction heat produced by cutting of the wafer 11 are taken into the cutting water and removed.

Here, unlike the wafer processing method according to the present embodiment, when a dicing tape including a glue layer is used in place of the sheet 27 and cutting water including cutting swarf reaches the dicing tape, the cutting swarf sometimes sticks to the glue layer. In this case, the cutting swarf sometimes detaches from the dicing tape in the subsequent step, reaching and sticking to the wafer 11. When cutting swarf sticks to the wafer 11, the quality of the device chips formed from the wafer 11 declines, posing a problem. In contrast, in the wafer processing method according to the present embodiment, the sheet 27 includes no glue layer. Thus, even if the cutting water including cutting swarf reaches the sheet 27, the cutting swarf is unlikely to stick to the sheet 27. Moreover, even in the case where the cutting swarf sticks to the sheet 27, the cutting swarf can easily be removed from the sheet 27. Hence, the cutting swarf is unlikely to move from the sheet 27 to the wafer 11, making it unlikely to reduce the quality of the device chips.

In the wafer processing method according to the present embodiment, after the dividing step S30, a removing step S40 of removing, from the sheet 27, the annular protruding portion 13 that has been cut off from the wafer 11 is performed. FIG. 8A is a perspective view schematically illustrating the wafer unit 31 in the removing step S40, and FIG. 8B is a cross sectional view schematically illustrating the wafer unit 31 and the removing unit 60 in the removing step S40. FIG. 8B includes a cross sectional view schematically illustrating the annular protruding portion 13 at the time of being removed from the sheet 27 in the removing step S40. After being cut off from the wafer 11, the annular protruding portion 13 is pulled up and peeled off from the sheet 27. As a result, the portion which had been the circular recessed portion 15 of the wafer 11 is left on the sheet 27. That is, the wafer unit 31 in which the wafer 11 from which the annular protruding portion 13 has been removed, the sheet 27, and the annular frame 29 are integrated is obtained. When the wafer 11 is thereafter diced, individual device chips are obtained.

The removing step S40 is performed, for example, by the function of the removing unit 60. The removing unit 60 is, for example, incorporated in the cutting apparatus 38. Note, however, that the removing unit 60 may not be incorporated in the cutting apparatus 38, and the removing step S40 may be performed outside of the cutting apparatus 38. In the following description, a case in which the removing unit 60 is incorporated in the cutting apparatus 38 and the removing step S40 is performed by the removing unit 60 on the holding table 40 will be explained as an example for describing the removing step S40.

For example, as illustrated in FIGS. 8A and 8B, the removing step S40 is also performed on the holding table 40 following the dividing step S30. In the removing step S40, first, the base plate 64 of the removing unit 60 is disposed on the upper side of the wafer 11. Next, the base plate 64 is lowered in a state in which the removal claws 78 are projected outward in such a manner as to be positioned on the outer side with respect to the wafer 11. After being lowered to such an extent that the lower claws 78b of the removal claws 78 are positioned at the boundary between the sheet 27 and the annular protruding portion 13, the arm portion 62 is stopped being lowered. Subsequently, the removal claws 78 are moved toward the inner side of the base plate 64. At this time, the lower claws 78b are, for example, moved inward by 1.6 mm from the outer circumferential edge of the wafer 11. In the removing step S40, a plurality of removal claws 78 are inserted to the boundary between the sheet 27 and the annular protruding portion 13 in a state in which the removal claws 78 are disposed in a manner separated from one another at substantially equal intervals along the circumferential direction of the wafer 11.

Next, while the base plate 64 is rotated about the arm portion 62 as the rotational axis and the plurality of removal claws 78 are rotated along the outer circumference of the wafer 11, the arm portion 62 and the base plate 64 are lifted, so that the plurality of removal claws 78 are moved upward. Note that the rotational speed of the removal claws 78 is, for example, 10°/s, and each removal claw 78 is rotated 140° in 14 seconds. Further the lifting speed of the removal claws 78 is, for example, 0.14 mm/s. When the annular protruding portion 13 is separated from the sheet 27, the annular protruding portion 13 is removed from the sheet 27 (wafer unit 31).

In the present embodiment, as described above, the operation of rotationally moving the plurality of removal claws 78 about the wafer 11 and the operation of moving the plurality of removal claws 78 upward are performed together, so that, compared to the case in which each operation is performed individually, the annular protruding portion 13 can be removed from the sheet 27 in a short period of time. In addition, the annular protruding portion 13 is moved in a predetermined direction separating from the sheet 27 in association with the rotational movement of the removal claws 78, so that such an advantage that the annular protruding portion 13 does not stick to the sheet 27 again is obtained. Further, the removal claw 78 includes the upper claw 78a in addition to the lower claw 78b. Hence, although the annular protruding portion 13 that has been peeled off from the sheet 27 sometimes jumps up, the upper claw 78a is provided, so that the annular protruding portion 13 can only rise and move between the upper claw 78a and the lower claw 78b. As a result, the annular protruding portion 13 can be prevented from falling off.

Note that, when the annular protruding portion 13 is to be removed from the sheet 27 in the manner described above, an excessive load is applied on the annular protruding portion 13 on rare occasions, leading to cracking and chipping of the annular protruding portion 13. Following this, the generated swarf and fragments sometimes fall on the sheet 27 between the wafer 11 of the wafer unit 31 and the annular frame 29. However, since the sheet 27 includes no glue layer, the swarf and the fragments do not stick to the sheet 27. For example, when the wafer unit 31 is cleaned by a cleaning apparatus or the like, such swarf and fragments are extremely easily removed and do not remain on the sheet 27. Further, unlike the case in which the wafer 11 is strongly stuck to an adhesive tape by a glue layer, when the wafer 11 is fixed to the sheet 27 including no glue layer, the annular protruding portion 13 can be removed relatively easily. Hence, a large force does not act on the annular protruding portion 13 that is to be removed, making it less likely for breakage to occur or fragments to be generated. Thus, the fragments would not scatter and stick to the device chips formed by the wafer 11 being diced, preventing the quality of the device chips from deteriorating.

Further, UV rays need not be applied to the sheet 27 for removing the annular protruding portion 13 from the sheet 27, so that the region on the face side 11a of the wafer 11 that is to be used for device formation need not be narrowed down on the assumption that UV rays are to be applied. This also increases the productivity of the device chips.

Note that, in the dividing step S30 of the abovementioned embodiment, a case where the dividing groove 33 is formed in the wafer 11 with use of the cutting apparatus 38 on which the cutting blade 56 is mounted has been described, but the aspect of the present invention is not limited to this. That is, in the dividing step S30, a laser processing apparatus (not illustrated) that can apply a laser beam to the wafer 11 and perform laser processing on the wafer 11 may be used.

For example, a laser beam including a wavelength component absorbable by the wafer 11 is applied to a region in the wafer 11 where the dividing groove 33 is to be formed, and ablation processing is performed on the wafer 11. Alternatively, a laser beam including a wavelength component transmittable through the wafer 11 is converged in a region in the wafer 11 where the dividing groove 33 is to be formed, a modifying layer is formed in the wafer 11 along the region, and the wafer 11 is divided with the modified layer being used as the dicing initiating point. In these cases as well, the wafer processing method according to the aspect of the present invention can easily remove, from the sheet 27, the annular protruding portion 13 which has been cut off from the wafer 11. At this time, no large load acts on the annular protruding portion 13, and even if breakage or the like occurs in the annular protruding portion 13 and fragments fall on the sheet 27, the fragments can easily be removed from the sheet 27. Thus, fragments would not subsequently stick to the device chips, and high-quality device chips can be formed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method for processing a wafer including a reverse side which has an annular protruding portion on an outer circumferential portion thereof and a circular recessed portion in a region surrounded by the annular protruding portion, the wafer processing method comprising:
a wafer unit forming step of forming a wafer unit by fixing a sheet including no glue layer to a face side of the wafer and fixing an annular frame to an outer circumferential portion of the sheet;
a holding step of holding the wafer on a holding table via the sheet, after the wafer unit forming step;
a dividing step of forming a dividing groove in the circular recessed portion of the wafer and separating the annular protruding portion from the wafer, after the holding step; and
a removing step of removing the annular protruding portion from the sheet, after the dividing step.

2. The wafer processing method according to claim 1, wherein,
in the wafer unit forming step, the sheet is fixed to the wafer by being heated, pressed against, and thermocompression-bonded to the wafer.
